(19) United States
(12) Patent Application Publication
(10) Pub. No.: US 2025/0390381 A1
(43) Pub. Date: Dec. 25, 2025

(54) MEMORY INCLUDING ECC CIRCUIT AND OPERATION METHOD OF MEMORY

(71) Applicant: SK hynix Inc., Gyeonggi-do (KR)

(72) Inventors: Dong Yoon KA, Gyeonggi-do (KR); Sang Uhn CHA, Gyeonggi-do (KR); Kyeong Pil KANG, Gyeonggi-do (KR); Min Cheol PARK, Gyeonggi-do (KR)

(21) Appl. No.: 18/911,245

(22) Filed: Oct. 10, 2024

(30) Foreign Application Priority Data
Jun. 19, 2024 (KR) 10-2024-0079315

(51) Int. Cl. G06F 11/10

(52) U.S. Cl. CPC G06F 11/1044

(57) ABSTRACT

A memory including a first ECC decoder circuit configured to correct errors of first data having multiple bits and second data having one or more bits by using the first data, the second data, and a first parity and generate first error correction results, a second ECC decoder circuit configured to correct errors of the first data and third data having one or more bits by using the first data, the third data, and the first parity and generate second error correction results, and a first selection circuit configured to select one of the first error correction results and the second error correction results.

### CROSS-REFERENCE TO RELATED APPLICATION

This application claims priority under 35 U.S.C. § 119 (a) to Korean Patent Application No. 10-2024-0079315, filed on Jun. 19, 2024, the entire contents of which are incorporated herein by reference.

### BACKGROUND

### 1. Technical Field

Embodiments of the present disclosure generally relate to memory.

### 2. Related Art

Recently, in addition to a normal refresh operation, an additional refresh operation (hereinafter referred to as a “target refresh operation”) is performed on a memory cell of a specific row (or word line) having a good possibility that data will be lost due to a row hammering phenomenon. The row hammering phenomenon refers to a phenomenon in which the data of memory cells adjacent to a specific row are damaged due to a high activation count (or the number of active operations) for the specific row.

In order to prevent such a row hammering phenomenon, the number of active operations is counted for each row, and a target refresh operation is performed on rows adjacent to a row for which the number of active operations is a predetermined count or more.

### SUMMARY

In an embodiment of the present disclosure, memory may include a first error correction code (ECC) decoder circuit configured to correct errors of first data having multiple bits and second data having one or more bits by using the first data, the second data, and a first parity and generate first error correction results, a second ECC decoder circuit configured to correct errors of the first data and third data having one or more bits by using the first data, the third data, and the first parity and generate second error correction results, and a first selection circuit configured to select one of the first error correction results and the second error correction results.

In an embodiment of the present disclosure, an operating method of a memory may include reading first data having multiple bits from multiple first memory cells, reading second data having one or more bits from one or more second memory cells, reading third data having one or more bits from one or more third memory cells, reading a parity having multiple bits from multiple fourth memory cells, performing a first error correction operation by using the first data, the second data, and the parity to generate first error correction results, performing a second error correction operation by using the first data, the third data, and the parity to generate second error correction results, and selecting one of the first error correction results and the second error correction results.

In an embodiment of the present disclosure, a memory may include first memory cells disposed to be not adjacent to each other, second memory cells disposed to be not adjacent to each other, a first error correction code (ECC) decoder circuit configured to correct an error of first counting bits by using the first counting bits and a first parity that are read from the first memory cells, a second ECC decoder circuit configured to correct an error of second counting bits by using the second counting bits and a second parity that are read from the second memory cells, and a counting circuit configured to generate updated counting data by changing counting data including the first counting bits processed by the first ECC decoder circuit and the second counting bits processed by the second ECC decoder circuit. Each of the first memory cells may be adjacent to at least one of the second memory cells.

In an embodiment of the present disclosure, a memory may include first memory cells disposed to be not adjacent to each other, second memory cells disposed to be not adjacent to each other, third memory cells disposed to be not adjacent to each other, a first error correction code (ECC) decoder circuit configured to correct an error of first counting bits by using the first counting bits and a first parity that are read from the first memory cells, a second ECC decoder circuit configured to correct an error of second counting bits by using the second counting bits and a second parity that are read from the second memory cells, a third ECC decoder circuit configured to correct an error of third counting bits by using the third counting bits and a third parity that are read from the third memory cells, and a counting circuit configured to generate updated counting data by changing counting data including the first counting bits processed by the first ECC decoder circuit, the second counting bits processed by the second ECC decoder circuit, and the third counting bits processed by the third ECC decoder circuit. Each of the first memory cells may be adjacent to at least one cell, among the second memory cells and the third memory cells. Each of the second memory cells may be adjacent to at least one cell, among the first memory cells and the third memory cells. Each of the third memory cells may be adjacent to at least one cell, among the first memory cells and the second memory cells.

In an embodiment of the present disclosure, an operating method of a memory may include receiving a precharge command, reading first counting bits and a first parity from multiple first memory cells, reading second counting bits and a second parity from multiple second memory cells, performing a first error correction operation by using the first counting bits and the first parity, performing a second error correction operation by using the second counting bits and the second parity, updating counting data including the first counting bits on which the first error correction operation has been performed and the second counting bits on which the second error correction operation has been performed, generating a third parity by using third counting bits that are included in the updated counting data, generating a fourth parity by using fourth counting bits that are included in the updated counting data, writing the third counting bits and the third parity in the first memory cells, writing the fourth counting bits and the fourth parity into the second memory cells, and precharging a row corresponding to the first memory cells and the second memory cells.

### BRIEF DESCRIPTION OF THE DRAWINGS

FIG. 1 is a construction diagram of memory according to an embodiment of the present disclosure.

FIG. 2 is a construction diagram of a PRAC block of the memory according to a second embodiment of the present disclosure.

FIG. 3 is a construction diagram of the PRAC block of the memory according to a third embodiment of the present disclosure.

FIG. 4 is a construction diagram of the PRAC block of the memory according to a fourth embodiment of the present disclosure.

FIG. 5 is a construction diagram of the PRAC block of the memory according to a fifth embodiment of the present disclosure.

FIG. 6 is a construction diagram of the PRAC block of the memory according to a sixth embodiment of the present disclosure.

FIG. 7 is a construction diagram of an ECC engine illustrated in FIG. 6 according to an embodiment of the present disclosure.

FIG. 8 is a construction diagram of the other ECC engine illustrated in FIG. 6 according to an embodiment of the present disclosure.

### DETAILED DESCRIPTION

Hereinafter, embodiments according to the technical spirit of the present disclosure are described with reference to the accompanying drawings.

Embodiments of the present disclosure may provide a technology for implementing an excellent data correction capability while using parity having a small number of bits.

According to the embodiments of the present disclosure, the technology for implementing the excellent data correction capability while using parity having a small number of bits is provided.

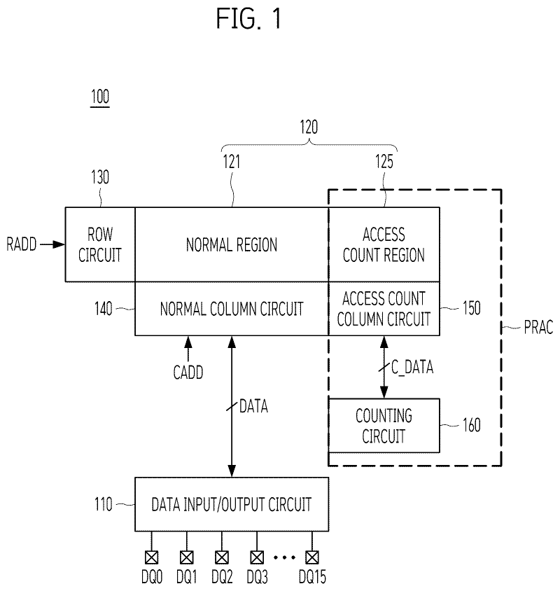

FIG. 1 is a construction diagram of memory 100 according to an embodiment of the present disclosure.

Referring to FIG. 1, in an embodiment, the memory 100 includes data pads DQ0 to DQ15, a data input and output (input/output) circuit 110, a cell array 120, a row circuit 130, a normal column circuit 140, an access count column circuit 150, and a counting circuit 160.

The data pads DQ0 to DQ15 may be pads to and from which data are input and output. Data having a burst length (BL) 16 may be input to and output from each of the data pads. That is, after the start of a write operation, 16-bit data may be input in series through each of the data pads DQ0 to DQ15. After the start of a read operation, 16-bit data may be output in series through each of the data pads DQ0 to DQ15. The number of data pads DQ0 to DQ15 and the BL 16 are merely examples, and the numbers may be different depending on the type and specifications of the memory 100.

The data input/output circuit 110 may input data through the data pads DQ0 to DQ15, and may align the input data and data for output, and may output the aligned data through the data pads DQ0 to DQ15. After the start of a write operation, the data input/output circuit 110 may receive data that are transferred to the data pads DQ0 to DQ15, and may output the received data by converting the received data in parallel to the data in serial. Furthermore, after the start of a read operation, the data input/output circuit 110 may convert data in serial that are received from the normal column circuit 140, to data in parallel, and may output the converted data through the data pads DQ0 to DQ15. After the start of a write operation and the start of a read operation, the data input/output circuit 110 may input or output data having 256 (=16*16) bits because data having the BL 16 are input and output through the sixteen data pads DQ0 to DQ15 after the start of a write operation and a read operation.

The cell array 120 includes multiple word lines, multiple bit lines, and multiple memory cells that are formed at intersecting points of the multiple word lines and the multiple bit lines, for example. In an embodiment, the cell array 120 includes a normal region 121 and an access count region 125. The normal region 121 may be a region in which write data are stored and which provides data stored in the region as read data. The access count region 125 may be a region in which the counting data of the number of active operations counted for each row (for each word line) are stored.

The row circuit 130 may activate a word line that is selected by a row address RADD, among the word lines of the cell array 120, after the start of an active operation. Furthermore, the row circuit 130 may inactivate an activated word line after the start of a precharge operation.

After the start of a write operation, the normal column circuit 140 may write data DATA in bit lines selected by a column address CADD, among bit lines of the normal region 121, that is, in memory cells that are connected to an activated word line and selected bit lines. After the start of a read operation, the normal column circuit 140 may read data DATA from bit lines selected by the column address CADD, among the bit lines of the normal region 121, that is, from memory cells that are connected to an activated word line and selected bit lines.

After the start of a precharge operation, the access count column circuit 150 may read counting data C_DATA from bit lines of the access count region 125, that is, from memory cells of the access count region 125 that are connected to an activated word line, and may transfer the read counting data to the counting circuit 160. Furthermore, when the counting circuit 160 updates the counting data C_DATA, the access count column circuit 150 may write the updated counting data C_DATA in bit lines of the access count region 125, that is, memory cells of the access count region 125 that are connected to an activated word line again. When the access count region 125 is accessed, the access count column circuit 150 might not use the column address CADD because all columns (i.e., all bit lines) are accessed.

The counting circuit 160 may update the counting data C_DATA that are received from the access count column circuit 150, by increasing the value of the counting data C_DATA. For example, the counting circuit 160 may increase the value of the counting data C_DATA by one (i.e., +1).

The access count region 125, the access count column circuit 150, and the counting circuit 160 are components that count an active count for each row. Accordingly, the access count region 125, the access count column circuit 150, and the counting circuit 160 are referred to as a per row access count (PRAC) block.

Various operations of the memory 100 will now be described.

### Active Operation

An active operation may be an operation of activating a row. After the start of an active operation, the row circuit 130 may activate a word line selected by the row address RADD, among the multiple word lines of the cell array 120. The data of memory cells that are connected to a selected word line may be sensed and amplified during an active operation.

### Write Operation

A write operation may be performed during an active operation. For example, if a third word line (No. 3) is in an activated state, a write operation may be performed on the No. 3 word line. After the start of a write operation, the data input/output circuit 110 may receive and align the data DATA that are transferred to the data pads DQ0 to DQ15, and may transfer the data DATA to the normal column circuit 140. The normal column circuit 140 may write the data DATA in bit lines selected by the column address CADD, among the bit lines of the normal region 121 of the cell array 120. That is, the data DATA may be written in memory cells connected to a word line that is selected and activated by the row circuit 130 and bit lines that are selected by the normal column circuit 140.

### Read Operation

A read operation may be performed during an active operation. For example, if a third word line (No. 3) is in an activated state, a read operation may be performed on the No. 3 word line. After the start of a read operation, the normal column circuit 140 may read the data DATA from bit lines selected by the column address CADD, among the bit lines of the normal region 121 of the cell array 120. That is, the data DATA may be read from memory cells connected to a word line that is selected and activated by the row circuit 130 and bit lines that are selected by the normal column circuit 140. The data DATA that are read by the normal column circuit 140 may be transferred to the data input/output circuit 110. The data input/output circuit 110 may output the data DATA through the data pads DQ0 to DQ15 by converting the data DATA in parallel to the data DATA in serial.

### Precharge Operation

A precharge operation is an operation that terminates an active operation. However, when a precharge command is applied to the memory 100, an operation of counting an active count for each row may be performed. Next, an operation of precharging a word line may be performed. That is, the precharge operation may be performed in order of (1) the reception of the precharge command by the memory 100, (2) the reading of the counting data C_DATA from the access count region 125 by the access count column circuit 150, (3) the update of the counting data C_DATA by the counting circuit 160, (4) the writing of the updated counting data C_DATA in the access count region 125 by the access count column circuit 150, and (5) the inactivation (or precharging) of an activated word line by the row circuit 130.

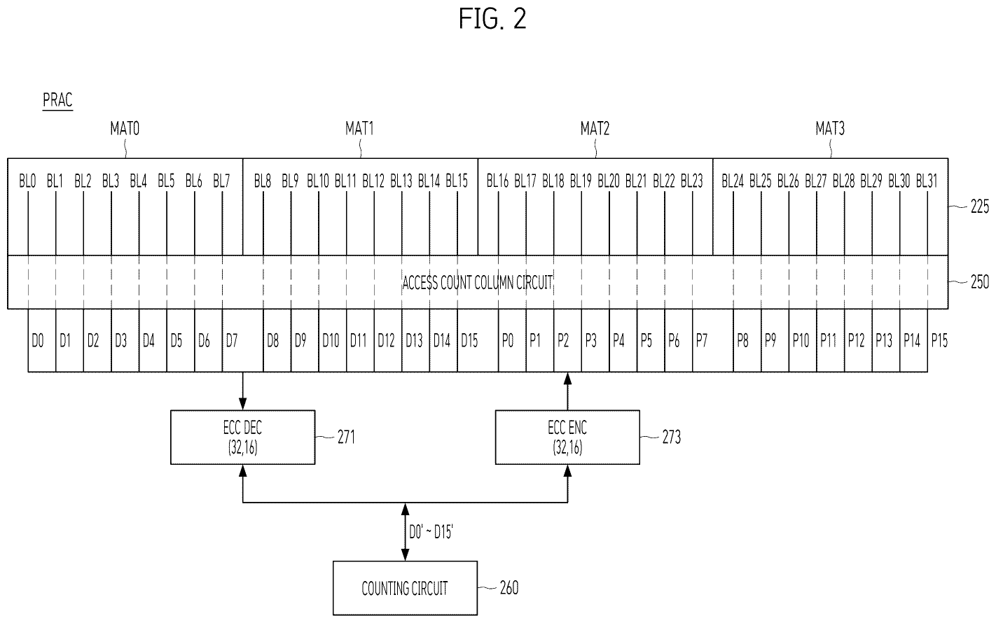

FIG. 2 is a construction diagram of the PRAC block of the memory 100 according to a second embodiment of the present disclosure.

Referring to FIG. 2, in an embodiment, the PRAC block includes an access count region 225, an access count column circuit 250, an error correction code (ECC) decoder circuit (ECC DEC) 271, an ECC encoder circuit (ECC ENC) 273, and a counting circuit 260.

The access count region 225 includes four cell matrices MAT0 to MAT3, for example. The cell matrices MAT0 to MAT3 may be regions including eight bit lines BL0 to BL7, BL8 to BL15, BL16 to BL23, and BL24 to BL31, respectively, for example.

The access count column circuit 250 may read 16-bit counting data D0 to D15 and a 16-bit parity P0 to P15 from the eight bit lines BL0 to BL7, BL8 to BL15, BL16 to BL23, and BL24 to BL31 or may write the 16-bit counting data D0 to D15 and the 16-bit parity P0 to P15 in the eight bit lines BL0 to BL7, BL8 to BL15, BL16 to BL23, and BL24 to BL31. The 16-bit counting data D0 to D15 may be the counting data of the number of active operations counted for each row. The 16-bit parity P0 to P15 may be for correcting an error of the 16-bit counting data D0 to D15.

The ECC decoder circuit 271 may correct an error of the 16-bit counting data D0 to D15 by using the 16-bit counting data D0 to D15 and the 16-bit parity P0 to P15 that are read by the access count column circuit 250, to generate counting data DO′ to D15′. The counting circuit 260 may update the counting data DO′ to D15′ an error of which has been corrected by the ECC decoder circuit 271, by increasing the value of the counting data DO′ to D15′. For example, the counting circuit 260 may increase the value of the counting data DO′ to D15′ by one (i.e., +1).

The ECC encoder circuit 273 generates the 16-bit parity P0 to P15 by using the updated counting data DO′ to D15′. The updated 16-bit counting data D0 to D15 and the 16-bit parity P0 to P15 that are generated by the ECC encoder circuit 271 may be written in the eight bit lines BL0 to BL7, BL8 to BL15, BL16 to BL23, and BL24 to BL31 by the access count column circuit 250. After the start of an encoding operation, the counting data DO′ to D15′ that are input to the ECC encoder circuit 273 may be the same as the 16-bit counting data D0 to D15 that are output by the ECC encoder circuit 273.

As described above, the PRAC block operates after the start of a precharge operation. The memory 100 including the PRAC block of FIG. 2 may operate in the following order, for example. That is, the memory 100 may operate in order of (1) the reception of a precharge command by the memory 100, (2) the reading of the 16-bit counting data D0 to D15 and the 16-bit parity P0 to P15 from the access count region 225 by the access count column circuit 250, (3) the correction of an error of the 16-bit counting data D0 to D15 by the ECC decoder circuit 271, (4) the update of the 16-bit counting data DO′ to D15′ by the counting circuit 260, (5) the generation of the 16-bit parity P0 to P15 corresponding to the updated counting data DO′ to D15′ by the ECC encoder circuit 273, (6) the writing of the updated 16-bit counting data D0 to D15 and the 16-bit parity P0 to P15 in the access count region 225 by the access count column circuit 250, and (7) the inactivation (or precharging) of an activated word line by the row circuit 130.

In (32, 16) that is written in the ECC encoder circuit 273 and the ECC decoder circuit 271, “32” indicates the size of a codeword of an ECC. That is, “32” indicates the number of bits of the sum of a message and parity. Furthermore, “16” indicates the size of the message. The ECC encoder circuit 273 and the ECC decoder circuit 271 may each be written as (32, 16) because the ECC encoder circuit 273 and the ECC decoder circuit 271 each use the 16-bit counting data D0 to D15 as a message and use the 16-bit parity P0 to P15.

The ECC encoder circuit 273 and the ECC decoder circuit 271 may be used to correct an error that occurs in the 16-bit counting data DO′ to D15′. The type of error that occurs often in memory cells is a 1-bit random error and a 2-bit adjacency error. The 1-bit random error means that an error randomly occurs in one memory cell. The 2-bit adjacency error means that errors simultaneously occur in two memory cells that are adjacent to each other. For example, errors may simultaneously occur in two memory cells that are adjacent to each other, due to the generation of a short between the memory cells of two bit lines (e.g., BL2 and BL3) that are adjacent to each other. For this reason, the ECC encoder circuit 273 and the ECC decoder circuit 271 may each be designed to be capable of correcting the 1-bit random error and the 2-bit adjacency error. That is, the ECC decoder circuit 271 may be designed to be capable of correcting the 1-bit random error and the 2-bit adjacency error (e.g., a simultaneous error of the data D0 and D1 or a simultaneous error of the data D2 and D3).

If the ECC encoder circuit 273 and the ECC decoder circuit 271 are each designed to be capable of correcting the 2-bit adjacency error, the ECC encoder circuit 273 and the ECC decoder circuit 271 each need to use the 16-bit parity P0 to P15 having a greater number of bits compared to the message D0 to D15, the complexity of each of the ECC encoder circuit 273 and the ECC decoder circuit 271 may be increased, and a processing time may be increased.

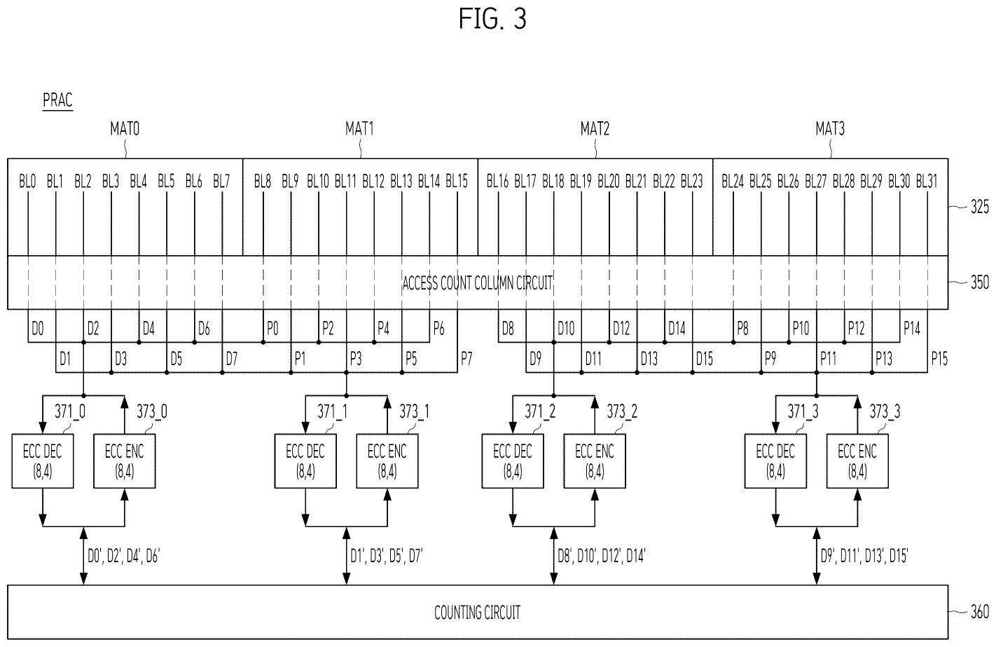

FIG. 3 is a construction diagram of the PRAC block of the memory 100 according to a third embodiment of the present disclosure.

Referring to FIG. 3, in an embodiment, the PRAC block includes an access count region 325, an access count column circuit 350, ECC decoder circuits (ECC DEC) 371_0, 371_1, 371_2, and 371_3, ECC encoder circuits (ECC ENC) 373_0, 373_1, 373_2, and 373_3, and a counting circuit 360.

The access count region 325 includes four cell matrices MAT0 to MAT3, for example. The cell matrices MAT0 to MAT3 may be regions including eight bit lines BL0 to BL7, BL8 to BL15, BL16 to BL23, and BL24 to BL31, respectively.

The access count column circuit 350 may read 16-bit counting data D0 to D15 and a 16-bit parity P0 to P15 from the eight bit lines BL0 to BL7, BL8 to BL15, BL16 to BL23, and BL24 to BL31, or may write the 16-bit counting data D0 to D15 and the 16-bit parity P0 to P15 in the eight bit lines BL0 to BL7, BL8 to BL15, BL16 to BL23, and BL24 to BL31. The 16-bit counting data D0 to D15 may be the counting data of the number of active operations counted for each row. The 16-bit parity P0 to P15 may be for correcting an error of the 16-bit counting data D0 to D15. In FIG. 3, correspondence relations between the 16-bit counting data D0 to D15 and the 16-bit parity P0 to P15, and the eight bit lines BL0 to BL7, BL8 to BL15, BL16 to BL23, and BL24 to BL31 may be different from those in FIG. 2.

In the embodiment of FIG. 3, the four independent ECC decoder circuits 371_0, 371_1, 371_2, and 371_3 and the four independent ECC encoder circuits 373_0, 373_1, 373_2, and 373_3 may be used. This may mean that the ECC decoder circuits 371_0, 371_1, 371_2, and 371_3 perform independent error correction operation and the ECC encoder circuits 373_0, 373_1, 373_2, and 373_3 perform independent parity generation operations.

The ECC decoder circuit 371_0 has a construction “(8, 4)”, and may correct an error of the 4-bit counting data DO, D2, D4, and D6 by using the 4-bit counting data DO, D2, D4, and D6 and the 4-bit parity P0, P2, P4, and P6. Counting data DO′, D2′, D4′, and D6′ an error of which has been corrected by the ECC decoder circuit 371_0 may be transferred to the counting circuit 360. The ECC encoder circuit 373_0 operates as a pair with the ECC decoder circuit 371_0, and generates the 4-bit parity P0, P2, P4, and P6 by using the counting data DO′, D2′, D4′, and D6′ that are transferred by the counting circuit 360.

The ECC decoder circuit 371_1 has a construction “(8, 4)”, and may correct an error of the 4-bit counting data D1, D3, D5, and D7 by using the 4-bit counting data D1, D3, D5, and D7 and the 4-bit parity P1, P3, P5, and P7. Counting data D1′, D3′, D5′, and D7′ an error of which has been corrected by the ECC decoder circuit 371_1 may be transferred to the counting circuit 360. The ECC encoder circuit 373_1 operates as a pair with the ECC decoder circuit 371_1, and generates the 4-bit parity P1, P3, P5, and P7 by using the counting data D1′, D3′, D5′, and D7′ that are transferred by the counting circuit 360.

The ECC decoder circuit 371_2 has a construction “(8, 4)”, and may correct an error of the counting data D8, D10, D12, and D14 by using the 4-bit counting data D8, D10, D12, and D14 and the 4-bit parity P8, P10, P12, and P14. Counting data D8′, D10′, D12′, and D14′ an error of which has been corrected by the ECC decoder circuit 371_2 may be transferred to the counting circuit 360. The ECC encoder circuit 373_2 operates as a pair with the ECC decoder circuit 371_2, and generates the parities P8, P10, P12, and P14 by using the counting data D8′, D10′, D12′, and D14′ that are transferred by the counting circuit 360.

The ECC decoder circuit 371_3 has a construction “(8, 4)”, and may correct an error of the 4-bit counting data D9, D11, D13, and D15 by using the 4-bit counting data D9, D11, D13, and D15 and the 4-bit parity P9, P11, P13, and P15. Counting data D9′, D11′, D13′, and D15′ an error of which has been corrected by the ECC decoder circuit 371_3 may be transferred to the counting circuit 360. The ECC encoder circuit 373_3 operates as a pair with the ECC decoder circuit 371_3, and generates the 4-bit parity P9, P11, P13, and P15 by using the counting data D9′, D11′, D13′, and D15′ that are transferred by the counting circuit 360.

The counting circuit 360 may update the counting data DO′ to D15′ by increasing the value of the counting data DO′ to D15′ an error of which has been corrected by the ECC decoder circuits 371_0 to 371_3. The counting data DO′ to D15′ that have been updated by the counting circuit 370 may be transferred to the ECC encoder circuits 373_0 to 373_3.

Each of the ECC decoder circuits 371_0 to 371_3 does not correct the data of memory cells that are adjacent to each other in the cell matrices. The data D1 that are adjacent to the data D0 that are corrected by the ECC decoder circuit 371_0 are corrected by the ECC decoder circuit 371_1, not the ECC decoder circuit 371_0. Likewise, the data D13 that are adjacent to the data D12 that are corrected by the ECC decoder circuit 371_2 are corrected by the ECC decoder circuit 383_3, not the ECC decoder circuit 382_2. This may mean that although each of the ECC decoder circuits 371_0 to 371_3 has only the 1-bit error correction capability, each of the ECC decoder circuits 371_0 to 371_3 can practically correct a 2-bit adjacency error. For example, although errors simultaneously occur in the data D8 of a memory cell of the bit line BL16 and the data D9 of a memory cell of the bit line BL17 because a short failure occurs in the bit line BL16 and the bit line BL17, the error of the data D8 may be corrected by the ECC decoder circuit 371_2, and the error of the data D9 may be corrected by the ECC decoder circuit 371_3.

That is, by independently constructing and arranging several ECC circuits 371_0 to 371_3 and 373_0 to 373_3 as in the embodiment of FIG. 3, each of the ECC decoder circuits 371_0 to 371_3 can substantially implement the 2-bit adjacency error correction capability although each of the ECC decoder circuits 371_0 to 371_3 has only the 1-bit error correction capability. Furthermore, the processing time of each of the ECC circuits 371_0 to 371_3 and 373_0 to 373_3 in FIG. 3 can be reduced because each of the ECC circuits 371_0 to 371_3 and 373_0 to 373_3 will be constructed to be small and simple compared to the ECC encoder circuit 271 and the ECC decoder circuit 273 in FIG. 2.

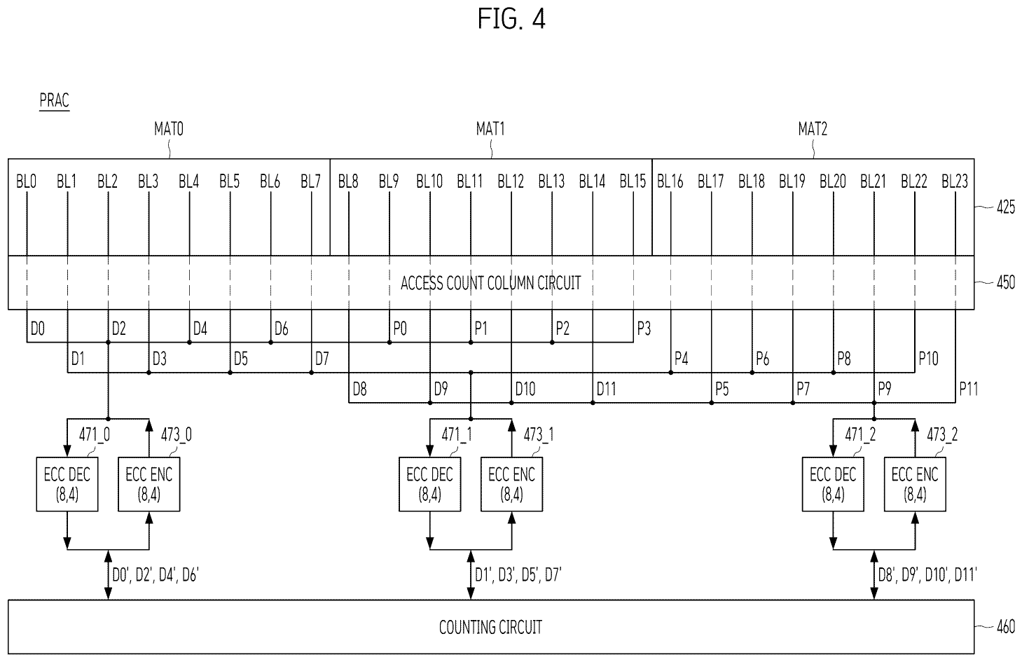

FIG. 4 is a construction diagram of the PRAC block of the memory 100 according to a fourth embodiment of the present disclosure.

Referring to FIG. 4, in an embodiment, the PRAC block includes an access count region 425, an access count column circuit 450, ECC decoder circuits (ECC DEC) 471_0, 471_1, and 471_2, ECC encoder circuits (ECC ENC) 473_0, 473_1, and 473_2, and a counting circuit 460.

The access count region 425 includes three cell matrices MAT0 to MAT2, for example. The cell matrices MAT0 to MAT2 may be regions including eight bit lines BL0 to BL7, BL8 to BL15, and BL16 to BL23, respectively. In the embodiment of FIG. 4, the counting data D0 to D11 have been illustrated as 12 bits. Accordingly, instead of four cell matrices, the three cell matrices MAT0 to MAT2 have been illustrated as being used.

The access count column circuit 450 may read the 12-bit counting data D0 to D11 and 12-bit parity P0 to P11 from the bit lines BL0 to BL23, and may write the 12-bit counting data D0 to D11 and the 12-bit parity P0 to P11 in the bit lines BL0 to BL23. The counting data D0 to D11 may be the counting data of the number of active operations counted for each row. The parity P0 to P11 may be for correcting an error of the counting data D0 to D11. Corresponding relations between the counting data D0 to D11 and the parity P0 to P11, and the bit lines BL0 to BL23 in FIG. 4 may be different from those in FIG. 3.

In the embodiment of FIG. 4, three independent ECC decoder circuits 471_0, 471_1, and 471_2 and three independent ECC encoder circuits 473_0, 473_1, and 473_2 may be used. This may mean that the ECC decoder circuits 471_0, 471_1, and 471_2 perform independent error correction operations and the ECC encoder circuits 473_0, 473_1, and 473_2 perform independent parity generation operations.

The ECC decoder circuit 471_0 has a construction “(8, 4)”, and may correct an error of the 4-bit counting data DO, D2, D4, and D6 by using the 4-bit counting data DO, D2, D4, and D6 and the 4-bit parity P0, P1, P2, and P3. Counting data DO′, D2′, D4′, and D6′ an error of which has been corrected by the ECC decoder circuit 471_0 may be transferred to the counting circuit 460. The ECC encoder circuit 473_0 operates as a pair with the ECC decoder circuit 471_0, and generates the parity P0, P1, P2, and P3 by using the counting data DO′, D2′, D4′, and D6′ that are transferred by the counting circuit 460.

The ECC decoder circuit 471_1 has a construction “(8, 4)”, and may correct an error of the 4-bit counting data D1, D3, D5, and D7 by using the 4-bit counting data D1, D3, D5, and D7 and the 4-bit parity P4, P6, P8, and P10. Counting data D1′, D3′, D5′, and D7′ an error of which has been corrected by the ECC decoder circuit 471_1 may be transferred to the counting circuit 460. The ECC encoder circuit 473_1 operates as a pair with the ECC decoder circuit 471_1, and generates the four-bit parity P4, P6, P8, and P10 by using the counting data D1′, D3′, D5′, and D7′ that are transferred by the counting circuit 460.

The ECC decoder circuit 471_2 has a construction “(8, 4)”, and may correct an error of the counting data D8, D9, D10, and D11 by using the 4-bit counting data D8, D9, D10, and D11 and the 4-bit parity P5, P7, P9, and P11. Counting data D8′, D9′, D10′, and D11′ an error of which has been corrected by the ECC decoder circuit 471_2 may be transferred to the counting circuit 460. The ECC encoder circuit 473_2 operates as a pair with the ECC decoder circuit 471_2, and generates the four-bit parity P5, P7, P9, and P11 by using the counting data D8′, D9′, D10′, and D11′ that are transferred by the counting circuit 460.

The counting circuit 460 updates the counting data DO′ to D11′ by increasing the value of the counting data DO′ to D11′ an error of which has been corrected by the ECC decoder circuits 471_0, 471_1, and 471_2. The counting data DO′ to D11′ that have been updated by the counting circuit 460 may be transferred to the ECC encoder circuits 473_0, 473_1, and 473_2.

Each of the ECC decoder circuits 471_0, 471_1, and 471_2 does not correct the data of memory cells that are adjacent to each other in the cell matrices. For example, the data D1 that are adjacent to the data D0 corrected by the ECC decoder circuit 471_0 are corrected by the ECC decoder circuit 471_1, not the ECC decoder circuit 471_0. This may mean that although each of the ECC decoder circuits 471_0, 471_1, and 471_2 has only the 1-bit error correction capability, each of the ECC decoder circuits 471_0, 471_1, and 471_2 can practically correct a 2-bit adjacency error.

That is, by independently constructing and arranging several ECC circuits 471_0 to 471_2 and 473_0 to 473_2 as in the embodiment of FIG. 4, each of the ECC decoder circuits 471_0 to 471_2 can substantially implement the 2-bit adjacency error correction capability although each of the ECC decoder circuits 471_0 to 471_2 has only the 1-bit error correction capability. Furthermore, the processing time of each of the ECC circuits 471_0 to 471_2 and 473_0 to 473_2 in FIG. 4 can be reduced because each of the ECC circuits 471_0 to 471_2 and 473_0 to 473_2 will be constructed to be small and simple compared to the ECC encoder circuit 271 and the ECC decoder circuit 273 in FIG. 2.

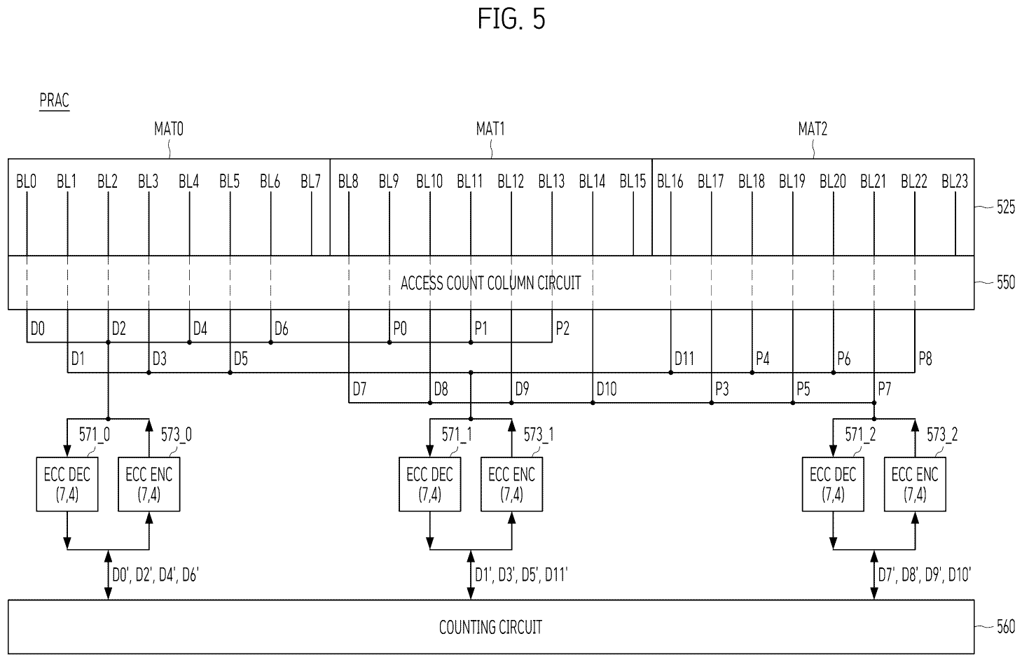

FIG. 5 is a construction diagram of the PRAC block of the memory 100 according to a fifth embodiment of the present disclosure. Referring to FIG. 5, in an embodiment, the PRAC block includes an access count region 525, an access count column circuit 550, ECC decoder circuits (ECC DEC) 571_0, 571_1, and 571_2, ECC encoder circuits (ECC ENC) 573_0, 573_1, and 573_2, and an counting circuit 560.

Each of the ECC circuits 571_0, 571_1, 571_2, 573_0, 573_1, and 573_2 in FIG. 5 may have a construction “(7, 4)”, not the construction “(8, 4)”. That is, each of the ECC circuits 571_0, 571_1, 571_2, 573_0, 573_1, and 573_2 may use a parity P0 to P8 including three bits, not four bits. Each of the ECC circuits 571_0, 571_1, 571_2, 573_0, 573_1, and 573_2 may use the 3-bit parity P0 to P8 because it is sufficient although each of the ECC circuits has only the 1-bit error correction capability.

The access count column circuit 550 may access seven bit lines BL0 to BL6, BL8 to BL14, and BL16 to BL22 in cell matrices MAT0 to MAT2 of the access count region 525, respectively, because each of the ECC circuits 571_0, 571_1, 571_2, 573_0, 573_1, and 573_2 has the construction “(7, 4)”. That is, each of the bit lines BL7, BL15, and BL23 at the outermost side of each of the seven bit lines BL0 to BL6, BL8 to BL14, and BL16 to BL22 of the cell matrices MAT0 to MAT2 might not be accessed.

The PRAC block in FIG. 5 may operate identically with the PRAC block in FIG. 4 except that each of the ECC circuits 571_0, 571_1, 571_2, 573_0, 573_1, and 573_2 has the construction “(7, 4)” and the seven bit lines BL0 to BL6, BL8 to BL14, and BL16 to BL22 are accessed in the cell matrices MAT0 to MAT2, respectively.

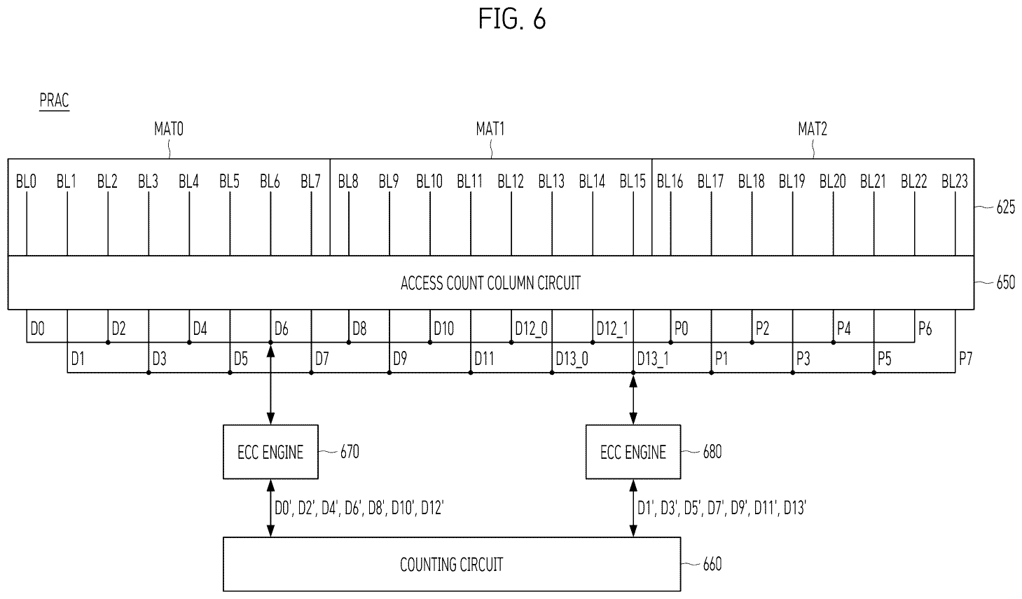

FIG. 6 is a construction diagram of the PRAC block of the memory 100 according to a sixth embodiment of the present disclosure.

Referring to FIG. 6, in an embodiment, the PRAC block includes an access count region 625, an access count column circuit 650, ECC engines 670 and 680, and a counting circuit 660.

The access count region 625 includes three cell matrices MAT0 to MAT2, for example. The cell matrices MAT0 to MAT2 may be regions including eight bit lines BL0 to BL7, BL8 to BL15, and BL16 to BL23, respectively.

The access count column circuit 650 may read 16-bit counting data D0 to D11, D12_0, D12_1, D13_0, and D13_1 and an 8-bit parity P0 to P7 from the bit lines BL0 to BL23, and may write the 16-bit counting data D0 to D11, D12_0, D12_1, D13_0, and D13_1 and the 8-bit parity P0 to P7 in the bit lines BL0 to BL23. The counting data DO to D11, D12_0, D12_1, D13_0, and D13_1 may be the counting data of the number of active operations counted for each row. The parity P0 to P7 may be for correcting an error of the counting data D0 to D11, D12_0, D12_1, D13_0, and D13_1. The bits D12_0 and D12_1 of the counting data may be bits that are the same data D12 and that have been written in different memory cells. The bits D13_0 and D13_1 of the counting data may also be bits that are the same data D13 and that have been written in different memory cells. The two bits D12 and D13, that is, the most significant bits (MSBs) in the counting data, may be redundantly written twice. That is, the counting data are the data of the 14-bit data D0 to D13, but may include 16 bits because the two bits D12 and D13 of the MSBs are redundantly written twice.

The ECC engine 670 may correct an error of the counting data DO, D2, D4, D6, D8, D10, D12_0, and D12_1 by using the counting data DO, D2, D4, D6, D8, D10, D12_0, and D12_1 and a 4-bit parity P0, P2, P4, and P6 that are read from the access count region 625. Furthermore, the ECC engine 670 generates the 4-bit parity P0, P2, P4, and P6 by using counting data DO′, D2′, D4′, D6′, D8′, D10′, and D12′ that have been updated by the counting circuit 660.

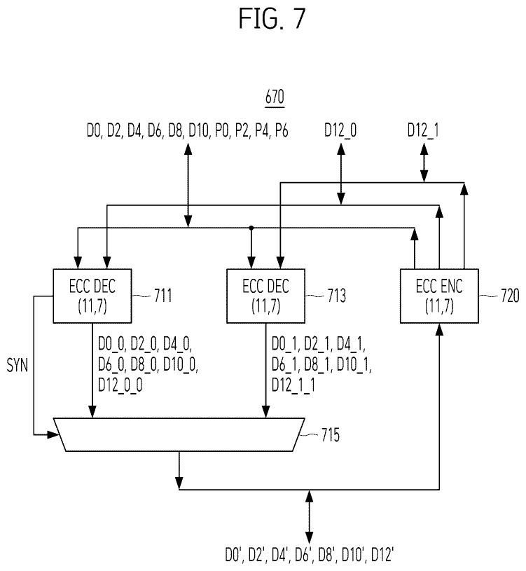

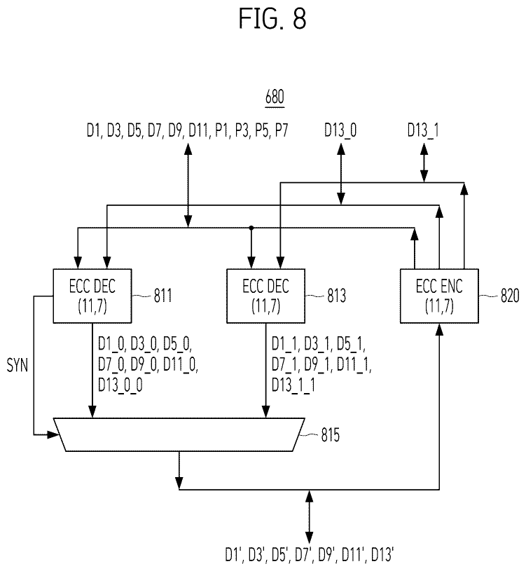

The ECC engine 680 may correct an error of the counting data D1, D3, D5, D7, D9, D11, D13_0, and D13_1 by using the counting data D1, D3, D5, D7, D9, D11, D13_0, and D13_1 and a 4-bit parity P1, P3, P5, and P7 that are read from the access count region 625. Furthermore, the ECC engine 680 generates the 4-bit parity P1, P3, P5, and P7 by using counting data D1′, D3′, D5′, D7′, D9′, D11′, and D13′ that have been updated by the counting circuit 660. Detailed constructions of the ECC engines 670 and 680 are described in detail with reference to FIGS. 7 and 8.

The counting circuit 660 may update the counting data DO′ to D13′ by increasing the value of the counting data DO′ to D13′ an error of which has been corrected by the ECC engines 670 and 680. The counting data DO′ to D13′ that have been updated by the counting circuit 660 may be transferred to the ECC engines 670 and 680.

FIG. 7 is a construction diagram of the ECC engine 670 illustrated in FIG. 6 according to an embodiment of the present disclosure.

Referring to FIG. 7, in an embodiment, the ECC engine 670 includes two ECC decoder circuits (ECC DEC) 711 and 713, a selection circuit 715, and an ECC encoder circuit (ECC ENC) 720.

The ECC decoder circuit 711 has a construction “(11, 7)”, and may correct an error of the counting data DO, D2, D4, D6, D8, D10, and D12_0 by using the counting data DO, D2, D4, D6, D8, D10, and D12_0 and the 4-bit parity P0, P2, P4, and P6. The ECC decoder circuit 711 may have the 1-bit error correction capability. The error correction results of the ECC decoder circuit 711 are indicated as D0_0, D2_0, D4_0, D6_0, D8_0, D10_0, and D12_0_0.

The ECC decoder circuit 713 has a construction “(11, 7)”, and may correct an error of the counting data DO, D2, D4, D6, D8, D10, and D12_1 by using the counting data DO, D2, D4, D6, D8, D10, and D12_1 and the 4-bit parity P0, P2, P4, and P6. The ECC decoder circuit 713 may be different from the ECC decoder circuit 711 that receives the bit D12_0, in that the ECC decoder circuit 713 receives the bit D12_1. The ECC decoder circuit 713 may have the 1-bit error correction capability. The error correction results of the ECC decoder circuit 713 are indicated as D0_1, D2_1, D4_1, D6_1, D8_1, D10_1, and D12_1_1.

The ECC decoder 711, the ECC decoder 713, and the ECC decoder 720 may be the same decoder. In other words, they may use the same H matrix.

The selection circuit 715 may select one of error correction results D0_0, D2_0, D4_0, D6_0, D8_0, D10_0, and D12_0_0 of the ECC decoder circuit 711 and error correction results D0_1, D2_1, D4_1, D6_1, D8_1, D10_1, and D12_1_1 of the ECC decoder circuit 713, and may output the selected results. The results of the error correction that are selected by the selection circuit 715 may become the error correction results DO′, D2′, D4′, D6′, D8′, D10′, and D12′ of the ECC engine 670.

The ECC decoder circuit 711 does not correct an error when any error is not present in the counting data DO, D2, D4, D6, D8, D10, and D12_1 and the 4-bit parity P0, P2, P4, and P6 that are input. The ECC decoder circuit 711 may find and correct an error of 1 bit in the bits DO, D2, D4, D6, D8, D10, and D12_0, P0, P2, P4, and P6 that are input when the corresponding error is present. Furthermore, when errors of two or more bits, which exceed an error correction capability, are present in the bits DO, D2, D4, D6, D8, D10, and D12_0, P0, P2, P4, and P6 that are input, the ECC decoder circuit 711 may correct an erroneous bit (i.e., a bit not having an error) by only recognizing that the error of two or more bits is present or recognizing that an error of 1 bit is present. For example, when an error is present in the bits DO and D6, the ECC decoder circuit 711 may increase the number of errors by miss-correcting the bit D5 not having an error. That is, operation results of the ECC decoder circuit 711 may include four cases: a) not error, b) an error of 1 bit is found and corrected, c) errors of two or more bits are found, and d) an error of 1 bit is miss-corrected due to errors of two or more bits. In this case, a dangerous case is the case d.

The ECC decoder circuit 711 generates a syndrome SYN by using the counting data DO, D2, D4, D6, D8, D10, and D12_0 and the 4-bit parity P0, P2, P4, and P6, and corrects a bit corresponding to the syndrome SYN, among the bits DO, D2, D4, D6, D8, D10, D12_0, P0, P2, P4, and P6. When a bit corresponding to the syndrome SYN is not present, a correction operation is not performed. When the value of the syndrome SYN corresponds to the bit D12_0, this may mean that the bit D12_0 is miss-corrected because an error is present in the bit D12_0 or an error is present in other bits. That is, when the value of the syndrome SYN corresponds to the bit D12_0, this may mean that there is a possibility that a bit may be wrong.

The selection circuit 715 receives the syndrome SYN of the ECC decoder circuit 711, and may select the error correction results D0_1, D2_1, D4_1, D6_1, D8_1, D10_1, and D12_1_1 of the ECC decoder circuit 713 when the value of the syndrome SYN corresponds to the bit D12_0. The selection circuit 715 selects the error correction results D0_0, D2_0, D4_0, D6_0, D8_0, D10_0, and D12_0_0 of the ECC decoder circuit 711 when the value of the syndrome SYN does not correspond to the bit D12_0. When the value of the syndrome SYN corresponds to the bit D12_0, this means that there is a possibility that the bit D12_0 may be miss-corrected as an erroneous value by the ECC decoder circuit 711. In this case, the selection circuit 715 selects the error correction results of the ECC decoder circuit 713, which will have the probability of being safer. The protection of the bit D12 can be strengthened because a decoding operation is dually performed by the ECC decoder circuits 711 and 713 and one of the results of the decoding operations of the ECC decoder circuits 711 and 713 is selected. The reason why the protection of the bit D12, among the many bits DO, D2, D4, D6, D8, D10, and D12, is strengthened is that the most important value, among the bits DO, D2, D4, D6, D8, D10, and D12 of the counting data, is the bit D12, that is, the MSB.

FIG. 7 illustrates that the selection circuit 715 receives the syndrome SYN of the ECC decoder circuit 711 and performs a selection operation depending on whether the value of the syndrome SYN corresponds to the bit D12_0. In contrast, the selection circuit 715 may be designed to select the error correction results D0_0, D2_0, D4_0, D6_0, D8_0, D10_0, and D12_0_0 of the ECC decoder circuit 711 when the selection circuit 715 receives a syndrome SYN of the ECC decoder circuit 713 and the value of the syndrome SYN corresponds to the bit D12_1 and to select the error correction results D0_1, D2_1, D4_1, D6_1, D8_1, D10_1, and D12_1_1 of the ECC decoder circuit 713 when the value of the syndrome SYN does not correspond to the bit D12_1.

The ECC encoder circuit 720 may generate the 4-bit parity P0, P2, P4, and P6 by using the counting data DO′, D2′, D4′, D6′, D8′, D10′, and D12′ that have been updated by the counting circuit 660. The ECC encoder circuit 720 may copy the bit D12′ and output the bits D12_0 and D12_1 having the same value.

FIG. 8 is a construction diagram of the ECC engine 680 illustrated in FIG. 6 according to an embodiment of the present disclosure.

Referring to FIG. 8, in an embodiment, the ECC engine 680 includes two ECC decoder circuits (ECC DEC) 811 and 813, a selection circuit 815, and an ECC encoder circuit (ECC DEC) 820.

The ECC decoder circuit 811 has a construction “(11, 7)”, and may correct an error of the counting data D1, D3, D5, D7, D9, D11, and D13_0 by using the counting data D1, D3, D5, D7, D9, D11, and D13_0 and the 4-bit parity P1, P3, P5, and P7. The ECC decoder circuit 811 may have the 1-bit error correction capability. The error correction results of the ECC decoder circuit 811 are indicated as D1_0, D3_0, D5_0, D7_0, D9_0, D11_0, and D13_0_0.

The ECC decoder circuit 813 has a construction “(11, 7)”, and may correct an error of the counting data D1, D3, D5, D7, D9, D11, and D13_1 by using the counting data D1, D3, D5, D7, D9, D11, and D13_1 and the 4-bit parity P1, P3, P5, and P7. The ECC decoder circuit 813 may be different from the ECC decoder circuit 811 that receives the bit D13_0, in that the ECC decoder circuit 813 receives the bit D13_1. The ECC decoder circuit 813 may have the 1-bit error correction capability. The error correction results of the ECC decoder circuit 813 are indicated as D1_1, D3_1, D5_1, D7_1, D9_1, D11_1, and D13_1_1.

The selection circuit 815 may select one of the error correction results D1_0, D3_0, D5_0, D7_0, D9_0, D11_0, and D13_0_0 of the ECC decoder circuit 811 and the error correction results D1_1, D3_1, D5_1, D7_1, D9_1, D11_1, and D13_1_1 of the ECC decoder circuit 813, and may output the selected error correction results. The error correction results that are selected by the selection circuit 815 may become error correction results D1′, D3′, D5′, D7′, D9′, D11′, and D13′ of the ECC engine 680.

Like the selection circuit 715, the selection circuit 815 may receive a syndrome SYN of the ECC decoder circuit 811, and may select the error correction results D1_1, D3_1, D5_1, D7_1, D9_1, D11_1, and D13_1_1 of the ECC decoder circuit 813 when the value of the syndrome SYN corresponds to the bit D13_0 and select the error correction results D1_0, D3_0, D5_0, D7_0, D9_0, D11_0, and D13_0_0 of the ECC decoder circuit 811 when the value of the syndrome SYN does not correspond to the bit D13_0. The protection of the bit D13 can be strengthened because a decoding operation is dually performed by the ECC decoder circuits 811 and 813 and one of the results of the decoding operations of the ECC decoder circuits 811 and 813 is selected. The reason why the protection of the bit D13, among the many bits D1, D3, D5, D7, D9, D11, D13, is strengthened is that the most important value, among the bits D1, D3, D5, D7, D9, D11, D13 of the counting data, is the bit D13, that is, the MSB.

The ECC encoder circuit 820 generates the 4-bit parity P1, P3, P5, and P7 by using the counting data D1′, D3′, D5′, D7′, D9′, D11′, and D13′ that have been updated by the counting circuit 660. The ECC encoder circuit 820 may copy the bit D13′ and output the bits D13_0 and D13_1 having the same value.

Referring to FIGS. 6 to 8, the independent ECC engines 670 and 680 correct the data of memory cells that are adjacent to each other. Accordingly, errors can be processed although the errors simultaneously occur in two memory cells that are adjacent to each other. Furthermore, the ECC engine 670 strengthens the protection of the bit D12 of the counting data D0 to D13. The ECC engine 680 strengthens the protection of the bit D13 of the counting data D0 to D13. Accordingly, an error that occurs in the counting data D0 to D13 can be efficiently corrected. It has been illustrated that the ECC engines 670 and 680 redundantly process the bits D12 and D13, respectively, for one bit. According to an embodiment, each of the ECC engines 670 and 680 may redundantly process two or more bits.

The technical spirit of the present disclosure has been described in detail based on the embodiments, but it is to be noted that the embodiments are provided for the descriptions thereof and not for restriction thereof. Furthermore, one of ordinary skill in the field to which the present disclosure pertains will understand that various embodiments are possible without departing from the technical spirit of the present disclosure.

The ECC circuits have been illustrated as correcting an error of counting data in the embodiments, but the embodiments of the present disclosure may be applied to correcting an error of various data in addition to the counting data.

While the present disclosure contains many embodiments, these should not be construed as limitations on the scope of any invention or of what may be claimed, but rather as descriptions of features that may be specific to particular embodiments of the invention. Certain features that are described in the context of separate embodiments can also be implemented in combination in a single embodiment. Conversely, various features that are described in the context of a single embodiment can also be implemented in multiple embodiments separately or in any suitable sub-combination. Moreover, although features may be described above as acting in certain combinations, one or more features from a combination can in some cases be excised from the combination, and the combination may be directed to a sub-combination or variation of a sub-combination. Furthermore, the embodiments may be combined to form additional embodiments.

What is claimed is:

1. A memory comprising:
a first error correction code (ECC) decoder circuit configured to correct errors of first data having multiple bits and second data having one or more bits by using the first data, the second data, and a first parity, and generate first error correction results;
a second ECC decoder circuit configured to correct errors of the first data and third data having one or more bits by using the first data, the third data, and the first parity, and generate second error correction results; and
a first selection circuit configured to select one of the first error correction results and the second error correction results.

2. The memory of claim 1, wherein the second data and the third data are read from different memory cells and have an identical value with each other.

3. The memory of claim 2, wherein:
each of the bits of the second data is more important than each of the bits of the first data, and
each of the bits of the third data is more important than each of the bits of the first data.

4. The memory of claim 1, wherein the first selection circuit performs a selection operation on the first error correction results and the second error correction results based on a value of a syndrome that is generated by the first ECC decoder circuit.

5. The memory of claim 4, wherein the first selection circuit selects the second error correction results when the first ECC decoder circuit corrects the second data, and selects the first error correction results when the first ECC decoder circuit does not correct the second data.

6. The memory of claim 1, further comprising a first ECC encoder circuit configured to generate the first parity.

7. The memory of claim 6, wherein the first ECC decoder circuit, the second ECC decoder circuit, and the first ECC encoder circuit use an identical H matrix.

8. The memory of claim 1, further comprising:
a third ECC decoder circuit configured to correct errors of fourth data having multiple bits and fifth data having one or more bits by using the fourth data, the fifth data, and a second parity, and generate third error correction results;
a fourth ECC decoder circuit configured to correct errors of the fourth data and sixth data having one or more bits by using the fourth data, the sixth data, and the second parity, and generate fourth error correction results; and
a second selection circuit configured to select one of the third error correction results and the fourth error correction results.

9. The memory of claim 8, further comprising a cell array,
wherein the bits of the first data are read from first memory cells that are not adjacent to each other, among memory cells of the cell array,
wherein the bits of the fourth data are read from second memory cells that are not adjacent to each other, among the memory cells of the cell array, and
wherein each of the first memory cells is adjacent to at least one of the second memory cells.

10. The memory of claim 8, wherein the fifth data and the sixth data are read from different memory cells and have an identical value with each other.

11. The memory of claim 10, wherein:
each of the bits of the fifth data is more important than each of the bits of the fourth data, and
each of the bits of the sixth data is more important than each of the bits of the fourth data.

12. The memory of claim 8, wherein the second selection circuit performs a selection operation on the third error correction results and the fourth error correction results based on a value of a syndrome that is generated by the third ECC decoder circuit.

13. The memory of claim 12, wherein the second selection circuit selects the fourth error correction results when the third ECC decoder circuit corrects the fifth data, and selects the third error correction results when the third ECC decoder circuit does not correct the fifth data.

14. The memory of claim 8, further comprising a second ECC encoder circuit configured to generate the second parity.

15. The memory of claim 8, wherein the first to sixth data are generated by counting a number of active operations for each row.

16. An operating method of a memory, the operating method comprising:
reading first data having multiple bits from multiple first memory cells;
reading second data having one or more bits from one or more second memory cells;
reading third data having one or more bits from one or more third memory cells;
reading a parity having multiple bits from multiple fourth memory cells;
performing a first error correction operation by using the first data, the second data, and the parity to generate first error correction results;
performing a second error correction operation by using the first data, the third data, and the parity to generate second error correction results; and
selecting one of the first error correction results and the second error correction results.

17. The operating method of claim 16, further comprising:
prior to the reading of the first to third data and the reading of the parity,
generating a write parity by using write data;
writing some bits of the write data in the multiple first memory cells;
redundantly writing remaining bits of the write data in the one or more second memory cells and the one or more third memory cells; and
writing the write parity in the multiple fourth memory cells.

18. The operating method of claim 16, further comprising:
reading fourth data having multiple bits from multiple fifth memory cells;
reading fifth data having one or more bits from one or more sixth memory cells;
reading sixth data having one or more bits from one or more seventh memory cells;
reading a parity having multiple bits from multiple eighth memory cells;
performing a third error correction operation by using the fifth data, the sixth data, and the parity to generate third error correction results;
performing a fourth error correction operation by using the fifth data, the seventh data, and the parity to generate fourth error correction results; and
selecting one of the third error correction results and the fourth error correction results.

19. The operating method of claim 18, wherein:
the first memory cells are not adjacent to each other,
the fifth memory cells are not adjacent to each other, and
each of the first memory cells is adjacent to at least one of the fifth memory cells.

20. The operating method of claim 17, wherein each of the remaining bits of the write data is more important than each of the some bits of the write data.

21. The operating method of claim 16, wherein the selecting one of the first error correction results and the second error correction results includes selecting the second error correction results when the second data are corrected in the first error correction operation, and selecting the first error correction results when the second data are not corrected in the first error correction operation.
